(19) United States
(12) Patent Application Publication
(10) Pub. No.: US 2025/0372456 A1
(43) Pub. Date: Dec. 4, 2025

(54) SUBSTRATE PROCESSING APPARATUS, CALIBRATION SUBSTRATE, AND CALIBRATION METHOD

(71) Applicant: Tokyo Electron Limited, Tokyo (JP)

(72) Inventors: Tetsuya SAKAZAKI, Kumamoto (JP); Hiroshi MARUMOTO, Leuven (BE)

(21) Appl. No.: 19/211,657

(22) Filed: May 19, 2025

(30) Foreign Application Priority Data
May 31, 2024 (JP) 2024-088729

(51) Int. Cl. H01L 21/66; H01L 21/67

(52) U.S. Cl. CPC H01L 22/12; H01L 21/67051; H01L 21/67103; H01L 21/67155; H01L 21/67167; H01L 21/67248

(57) ABSTRACT

A substrate processing apparatus includes a holding unit that holds a substrate or a calibration substrate, a heating unit that heats the substrate or the calibration substrate held by the holding unit, and a radiation temperature sensor that detects infrared radiation emitted from the substrate or the calibration substrate and measures temperature distribution of the substrate or the calibration substrate. The calibration substrate includes a first main surface facing the heating unit and a second main surface opposite the first main surface and measured for temperature distribution by the radiation temperature sensor. The second main surface includes a first portion where a first material is exposed, and a second portion where a second material with a lower emissivity than the first material is exposed.

### CROSS-REFERENCE TO RELATED APPLICATIONS

This application is based on and claims priority from Japanese Patent Application No. 2024-088729, filed on May 31, 2024, with the Japan Patent Office, the disclosure of which is incorporated herein in its entirety by reference.

### TECHNICAL FIELD

The present disclosure relates to a substrate processing apparatus, a calibration substrate, and a calibration method.

### BACKGROUND

International Patent Publication No. WO 2003/021657 discloses a liquid processing apparatus that processes the back surface of a substrate using a processing liquid (e.g., a chemical liquid or a rinse liquid). The apparatus includes a support unit that supports a substrate, a rotation unit that rotates the substrate supported by the support, a supply unit that supplies a cleaning liquid to the back surface of the substrate supported by the support unit, and a cup arranged to surround the substrate supported by the support unit. When the cleaning liquid is supplied from the supply unit to the back surface of the rotating substrate, the cleaning liquid flows from the center toward the peripheral edge of the back surface of the substrate due to centrifugal force. Therefore, the back surface of the substrate is processed. The cleaning liquid spun off from the substrate is scattered toward the cup, where the cleaning liquid is collected and then discharged to the outside of the liquid processing apparatus.

### SUMMARY

A substrate processing apparatus includes a holding unit that holds a substrate or a calibration substrate, a heating unit that heats the substrate or the calibration substrate held by the holding unit, and a radiation temperature sensor that detects infrared radiation emitted from the substrate or the calibration substrate and measure temperature distribution of the substrate or the calibration substrate. The calibration substrate includes a first main surface facing the heating unit and a second main surface opposite the first main surface and measured for temperature distribution by the radiation temperature sensor. The second main surface includes a first portion where a first material is exposed, and a second portion where a second material with a lower emissivity than the first material is exposed.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view schematically illustrating an example of a substrate processing system.

FIG. 2 is a cross-sectional view schematically illustrating an example of a liquid processing unit.

FIG. 3 is a perspective view schematically illustrating an example of the temperature measurement range of a radiation temperature sensor for each liquid processing unit.

FIG. 4 is a top view illustrating an example of a calibration substrate.

FIG. 5 is a block diagram illustrating an example of a main portion of the liquid processing unit in FIG. 2.

FIG. 6 is a schematic diagram illustrating an example of a hardware configuration of a controller.

FIG. 7A is a captured image illustrating an example of the temperature distribution on the upper surface of the calibration substrate acquired by the radiation temperature sensor, and FIG. 7B is a captured image illustrating an example of a processed image in which a boundary line is indicated along the boundary between a high emissivity member and the upper surface of the calibration substrate in the captured image of FIG. 7A.

FIGS. 8A to 8C are respectively boundary line images extracted from processed images obtained by acquiring the temperature distribution of the calibration substrate using the radiation temperature sensor in different liquid processing units.

FIG. 9A is a pre-calibration image obtained by simply superimposing the respective boundary line images of FIGS. 8A to 8C, and FIG. 9B is a post-calibration image obtained by superimposing the respective boundary line images of FIGS. 8A to 8C such that boundary lines are substantially overlapped with each other.

FIG. 10 is a cross-sectional view schematically illustrating another example of a liquid processing unit.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

In the following description, the same reference numerals are used for the same elements or elements having the same functions, and redundant descriptions thereof are omitted. In addition, in this specification, the terms “upper,” “lower,” “right,” and “left” in the drawings are based on the orientation of the reference numerals in the drawings.

### [Substrate Processing System]

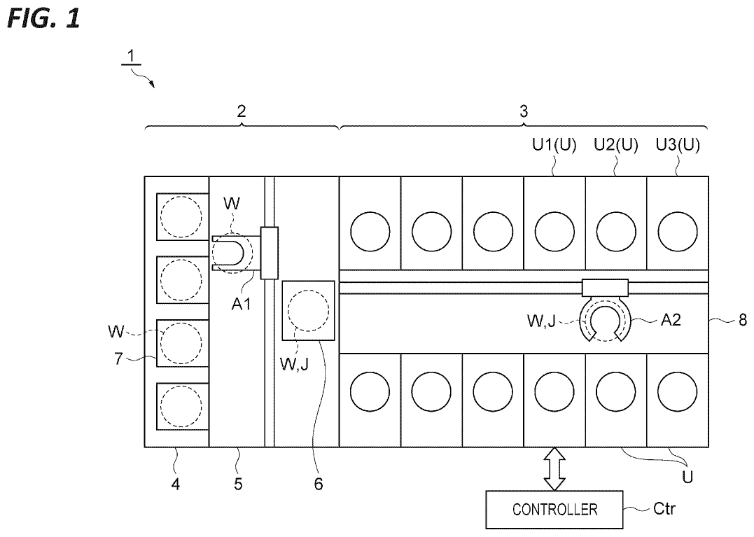

First, a substrate processing system 1 (substrate processing apparatus) configured to process a substrate W will be described with reference to FIG. 1. The substrate processing system 1 includes a loading/unloading station 2, a processing station 3, and a controller Ctr (control unit). The loading/unloading station 2 and the processing station 3 may be aligned in a single row, for example, in the horizontal direction.

The substrate W may have a disc shape, or may have a polygonal or another non-circular plate shape. The substrate W may also have a cutout formed in a portion thereof. The cutout may be, for example, a notch (such as a U-shaped or V-shaped groove), or may be a linear portion extending in a straight line shape (so-called “orientation flat”). The substrate W may be, for example, a semiconductor substrate (silicon wafer), a glass substrate, a mask substrate, a flat panel display (FPD) substrate, or various other types of substrates. The diameter of the substrate W may be, for example, in a range of approximately 200 mm to 450 mm.

The loading/unloading station 2 includes a placement section 4, a loading/unloading section 5, and a shelf unit 6. The placement section 4 includes a plurality of placement tables (not illustrated) arranged in the width direction (the up-down direction in FIG. 1). Each placement table is configured to place a carrier 7 thereon. The carrier 7 is configured to accommodate at least one substrate W in a sealed state. The carrier 7 includes an opening/closing door (not illustrated) for the entrance/exit of the substrate W.

The loading/unloading section 5 is arranged adjacent to the placement section 4 in the direction in which the loading/unloading station 2 and the processing station 3 are aligned (the left-right direction in FIG. 1). The loading/unloading section 5 includes an opening/closing door (not illustrated) provided relative to the placement section 4. Both the opening/closing door of the carrier 7 and the opening/closing door of the loading/unloading section 5 are opened simultaneously in a state where the carrier 7 is placed on the placement section 4, thereby allowing communication between the inside of the loading/unloading section 5 and the inside of the carrier 7.

The loading/unloading section 5 incorporates a transfer arm A1 and the shelf unit 6 (accommodation chamber). The transfer arm A1 is configured to allow horizontal movement in the width direction of the loading/unloading section 5, up/down movement in the vertical direction, and pivot motion around a vertical axis. The transfer arm A1 is configured to take out the substrate W from the carrier 7 and deliver the substrate W to the shelf unit 6, and also to take out the substrate W from the shelf unit 6 and return the substrate W into the carrier 7. The shelf unit 6 is located near the processing station 3 and is configured to accommodate the substrate W and a calibration substrate J (to be described in detail later).

The processing station 3 includes a transfer section 8 and a plurality of liquid processing units U. The transfer section 8 extends horizontally, for example, in the direction in which the loading/unloading station 2 and the processing station 3 are aligned (the left-right direction in FIG. 1). The transfer section 8 incorporates a transfer arm A2 (transfer unit). The transfer arm A2 is configured to allow horizontal movement in the longitudinal direction of the transfer section 8, up/down movement in the vertical direction, and pivot motion around a vertical axis. The transfer arm A2 is configured to take out the substrate W or the calibration substrate J from the shelf unit 6 and deliver the substrate W or the calibration substrate J to the liquid processing unit U and also to take out the substrate W or the calibration substrate J from the liquid processing unit U and return the substrate W or the calibration substrate J into the shelf unit 6.

The liquid processing units U are arranged to be aligned in a single row along the longitudinal direction of the transfer section 8 (the left-right direction in FIG. 1) on each of both sides of the transfer section 8. As illustrated in FIG. 1, the liquid processing units U may include liquid processing units U1 to U3. The positions of the liquid processing units U1 to U3 in the processing station 3 are not limited to the positions illustrated in FIG. 1.

The controller Ctr, which will be described in detail later, is configured to control the substrate processing system 1 either partially or entirely.

### [Liquid Processing Unit]

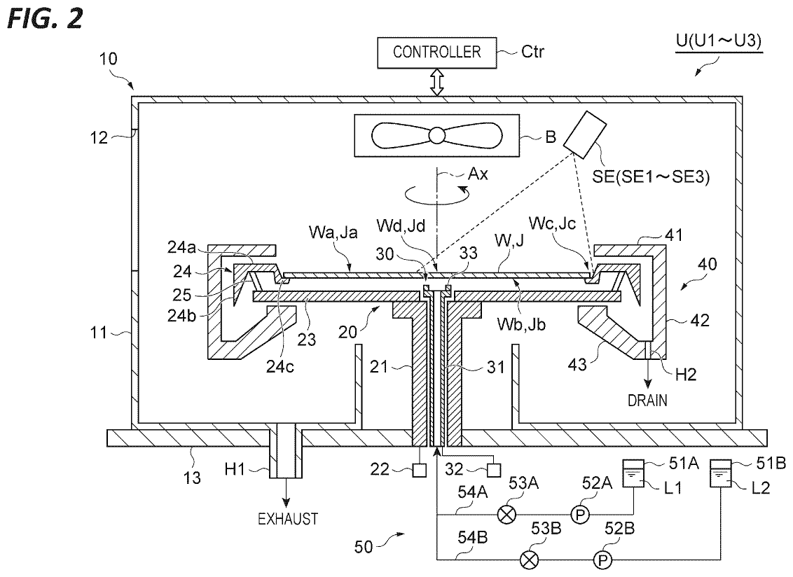

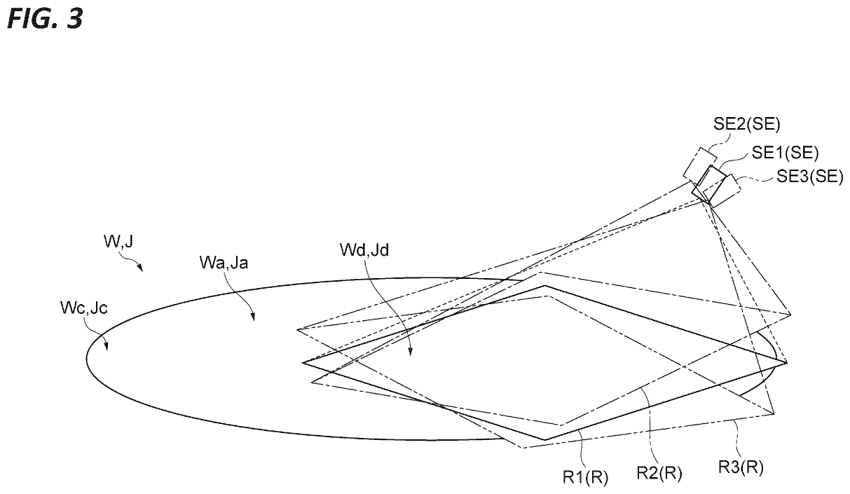

Next, the liquid processing unit U will be described with reference to FIGS. 2 and 3. The liquid processing unit U is configured to perform predetermined liquid processing (e.g., removal of contaminants or foreign substances, etching, or cleaning) on the substrate W. The liquid processing unit U may be, for example, a single-wafer type cleaning apparatus that cleans the substrate W one by one through spin cleaning.

As illustrated in FIG. 2, the liquid processing unit U includes a housing 10, a rotation unit 20, a lift unit 30, a cover member 40, a supply unit 50, a blower B, and a radiation temperature sensor SE. In addition, in the specification, the radiation temperature sensors SE included in the liquid processing units U1 to U3 may be referred to as radiation temperature sensors SE1 to SE3, respectively.

The housing 10 (processing chamber, first processing chamber, second processing chamber) mainly accommodates the rotation unit 20, the lift unit 30, the cover member 40, and the blower B inside. A loading/unloading port 12 is formed on a sidewall 11 of the housing 10. The substrate W or the calibration substrate J is loaded to the inside of the housing 10 and is also unloaded from the housing 10 to the outside through the loading/unloading port 12 by the transfer arm A2. An exhaust pipe H1 is provided on a bottom wall 13 of the housing 10 to extend downward. The exhaust pipe H1 is connected to a suction pump (not illustrated) and functions as an exhaust flow path for discharging a gas inside the cover member 40 to the outside of the housing 10.

The rotation unit 20 (holding unit, another holding unit, first holding unit, second holding unit) includes a rotating shaft 21, a drive mechanism 22, a support plate 23, and an annular member 24. The rotating shaft 21 is a hollow tubular member extending along the vertical direction. The rotating shaft 21 is attached to the bottom wall 13 of the housing 10 so as to be rotatable around a central axis Ax, which extends along the vertical direction.

The drive mechanism 22 is connected to the rotating shaft 21. The drive mechanism 22 is configured to operate based on an operation signal from the controller Ctr and to rotate the rotating shaft 21. The drive mechanism 22 may be a power source such as an electric motor.

The support plate 23 is, for example, a flat plate with an annular shape and extends horizontally. In other words, a through-hole is formed at the center of the support plate 23. The inner periphery of the support plate 23 is connected to the tip end of the rotating shaft 21. Therefore, the support plate 23 is configured to rotate around the central axis Ax of the rotating shaft 21 as the rotating shaft 21 rotates.

The annular member 24 has an annular shape and is arranged to surround the outer periphery of the support plate 23. The annular member 24 is connected to the outer periphery of the support plate 23 by a plurality of connection members 25. Accordingly, the annular member 24 is configured to rotate around the central axis Ax of the rotating shaft 21 as the rotating shaft 21 rotates.

The annular member 24 includes an upper wall portion 24a, a sidewall portion 24b, and a plurality of support portions 24c. The upper wall portion 24a is, for example, a plate-like body with an annular shape and extends horizontally. The sidewall portion 24b may have, for example, a cylindrical shape. The upper end of the sidewall portion 24b may be integrally connected to the outer periphery of the upper wall portion 24a. The sidewall portion 24b may be tapered, narrowing as it extends downward.

The support portions 24c have a substantially L-shaped cross section and are configured to support the peripheral edge Wc of the substrate W or the peripheral edge Jc of the calibration substrate J on the upper surface of the substantially horizontally extending tip end. Specifically, the support portions 24c hold the substrate W or the calibration substrate J substantially horizontally, with the upper surface Wa of the substrate W or the upper surface Ja (second main surface) of the calibration substrate J facing upward and the lower surface Wb of the substrate W or the lower surface Jb (first main surface) of the calibration substrate J facing downward. Therefore, when the rotating shaft 21 is rotated by the drive mechanism 22 in a state where the substrate W or the calibration substrate J is supported by the support portions 24c (hereinafter simply referred to as “supported state”), the substrate W or the calibration substrate J rotates around the central axis Ax. In other words, the rotation unit 20 is configured to rotate the substrate W or the calibration substrate J around the central axis Ax.

The support portions 24c may be integrally connected to the inner periphery of the upper wall portion 24a to protrude downward from the inner periphery of the upper wall portion 24a. The support portions 24c may be arranged at substantially equal intervals to form a circular shape as a whole when viewed from above. In other words, the annular member 24 is configured to surround the substrate W or the calibration substrate J from the outside in the supported state.

The lift unit 30 (heating unit, another heating unit, first heating unit, second heating unit) includes a shaft member 31, a drive mechanism 32, and a plurality of support pins 33. The shaft member 31 is a hollow tubular member extending along the vertical direction. The shaft member 31 is configured to be rotatable around the central axis Ax and be movable up and down in the up-down direction. The shaft member 31 is inserted through the inside of the rotating shaft 21.

The drive mechanism 32 is connected to the shaft member 31. The drive mechanism 32 is configured to operate based on an operation signal from the controller Ctr and to move the shaft member 31 up and down. The drive mechanism 32 may move the shaft member 31 up and down between a raised position (not illustrated) where the support pins 33 are located above the support portions 24c and a lowered position (see, e.g., FIG. 2) where the support pins 33 are located below the support portions 24c. The drive mechanism 32 may be a power source such as a linear actuator.

The support pins 33 are provided on the shaft member 31 to protrude upward from the upper end of the shaft member 31. The support pins 33 are configured to support the substrate W or the calibration substrate J by making contact at the tips thereof with the lower surface Wb of the substrate W or the lower surface Jb of the calibration substrate J. In other words, the support pins 33 face the lower surface Wb of the substrate W or the lower surface Jb of the calibration substrate J in the supported state. The support pins 33 may have, for example, a cylindrical shape or a truncated cone shape. The support portions 33 may be arranged at substantially equal intervals to form a circular shape as a whole when viewed from above.

The cover member 40 has an annular shape as a whole and is provided to surround the annular member 24 and the support plate 23 from the outside. The cover member 40 functions as a liquid collection container that receives processing liquids L1 and L2 supplied to the lower surface Wb of the substrate W and spun off from the substrate W.

The cover member 40 may include an upper wall portion 41, a sidewall portion 42, and a bottom wall portion 43. The upper wall portion 41 is, for example, a plate-like body with an annular shape and extends horizontally. When viewed from above, the upper wall portion 41 does not overlap with the substrate W or the calibration substrate J in the supported state.

The sidewall portion 42 may have, for example, a cylindrical shape. The upper end of the sidewall portion 42 may be integrally connected to the outer periphery of the upper wall portion 41. The lower end of the sidewall portion 42 may be integrally connected to the outer periphery of the bottom wall portion 43. The bottom wall portion 43 may be inclined upward as it extends radially inward. A through-hole H2 is provided at the bottom of the bottom wall portion 43. The through-hole H2 functions as a drainage flow path for discharging the collected processing liquids L1 and L2 from the cover member 40 to the outside of the housing 10.

The supply unit 50 (heating unit, another heating unit, first heating unit, second heating unit) is configured to supply the processing liquids L1 and L2 to the lower surface Wb of the substrate W or the lower surface Jb of the calibration substrate J through the inside of the shaft member 31. In other words, the shaft member 31 functions as a nozzle for supplying the processing liquids L1 and L2 to the lower surface Wb of the substrate W. The supply unit 50 may supply the processing liquids L1 and L2 to the lower surface Wb of the substrate W or the lower surface Jb of the calibration substrate J while the substrate W or the calibration substrate J is being rotated by the rotation unit 20. The supply unit 50 includes liquid sources 51A and 51B, pumps 52A and 52B, valves 53A and 53B, and pipes 54A and 54B.

The liquid source 51A functions as a supply source for the processing liquid L1. The processing liquid L1 may be, for example, a chemical liquid used to remove an unnecessary film such as SiN adhered to the lower surface Wb of the substrate W. The processing liquid L1 may be, for example, an acid-based processing liquid or an alkaline-based processing liquid. The acid-based processing liquid may include, for example, an SC-2 solution (a mixture of hydrochloric acid, hydrogen peroxide, and pure water), SPM (a mixture of sulfuric acid and hydrogen peroxide), HF solution (hydrofluoric acid), DHF solution (diluted hydrofluoric acid), and HNO₃+HF solution (a mixture of nitric acid and hydrofluoric acid). The alkaline-based processing liquid may include, for example, an SC-1 solution (a mixture of ammonia, hydrogen peroxide, and pure water), and hydrogen peroxide solution.

The pump 52A is configured to operate based on an operation signal from the controller Ctr, and to suction the processing liquid L1 from the liquid source 51A and send the processing liquid L1 to the shaft member 31 via the valve 53A and the pipe 54A. The valve 53A is configured to operate based on an operation signal from the controller Ctr and to open and close the pipe 54A before and after the valve 53A. The pipe 54A is connected to the liquid source 51A, pump 52A, and valve 53A in this order from the upstream side.

The liquid source 51B functions as a supply source for the processing liquid L2. The processing liquid L2 may be, for example, a rinsing liquid used to wash away foreign substances (e.g., particles or chemical residues). The processing liquid L2 may include, for example, deionized water (DIW). The processing liquid L2 may also be heated by a heating unit (e.g., a heater) (not illustrated). The temperature of the processing liquid L2 after heating by the heating unit may be, for example, in the range of approximately 60° C. to 70° C. When the heated processing liquid L2 is supplied to the lower surface Wb of the substrate W or the lower surface Jb of the calibration substrate J, the substrate W or the calibration substrate J is heated by the processing liquid L2. The supply of the heated processing liquid L2 to the lower surface Wb of the substrate W or the lower surface Jb of the calibration substrate J may be performed during the rotation of the substrate W or the calibration substrate J by the rotation unit 20.

The pump 52B is configured to operate based on an operation signal from the controller Ctr, and to suction the processing liquid L2 from the liquid source 51B and send the processing liquid L2 to the shaft member 31 via the valve 53B and the pipes 54A and 54B. The valve 53B is configured to operate based on an operation signal from the controller Ctr and to open and close the pipe 54B before and after the valve 53B. The pipe 54B is connected to the liquid source 51B, pump 52B, and valve 53B in this order from the upstream side. The downstream end of the pipe 54B is connected to the pipe 54A between the valve 53A and the shaft member 31.

The blower B is arranged above the rotation unit 20, the lift unit 30, and the cover member 40 inside the housing 10. The blower B is configured to operate based on a signal from the controller Ctr and to generate a downward airflow toward the upper surface Wa of the substrate W or the upper surface Ja of the calibration substrate J.

The radiation temperature sensor SE (another radiation temperature sensor, first radiation temperature sensor, second radiation temperature sensor) is configured to detect infrared radiation emitted from the substrate W or the calibration substrate J and measure the temperature distribution of the substrate W or the calibration substrate J. The radiation temperature sensor SE may be, for example, an infrared camera including an imaging element with a plurality of pixels arranged in a grid pattern to detect infrared radiation. The imaging element may have a square shape with the same number of pixels arranged vertically and horizontally, a rectangular shape with different numbers of pixels arranged vertically and horizontally, or a linear shape with a plurality of pixels aligned in a single row. The radiation temperature sensor SE is configured to measure the temperature at each pixel. In the following, a radiation temperature sensor SE (infrared camera) that uses an imaging element with 1024 pixels arranged in a 32×32 grid will be described as an example.

The radiation temperature sensor SE is attached inside the housing 10 so as to be located above the cover member 40 (above the substrate W or the calibration substrate J in the supported state), as illustrated in FIG. 2. In the case of the liquid processing unit U illustrated in FIG. 2, the blower B is arranged at the upper center of the housing 10, so that the radiation temperature sensor SE may be arranged in a region of the housing 10 that avoids the blower B (such as the upper side region of the housing 10). In this case, the radiation temperature sensor SE captures an image of the upper surface Wa of the substrate W or the upper surface Ja of the calibration substrate J in the supported state from an obliquely upward direction. In other words, in a plane including the upper surface Wa of the substrate W or the upper surface Ja of the calibration substrate J, an imaging area R (temperature measurement area) by the radiation temperature sensor SE has a substantially kite-like shape, as illustrated in FIG. 3. The imaging area R by the radiation temperature sensor SE may include the peripheral edge Wc and center Wd of the upper surface Wa of the substrate W, or may include the peripheral edge Jc and center Jd of the upper surface Ja of the calibration substrate J.

In each liquid processing unit U, the radiation temperature sensor SE may be attached inside the housing 10 at different positions and/or angles. In the example of FIG. 3, the attachment positions and attachment angles of the radiation temperature sensors SE1 to SE3 are slightly different from one another in the liquid processing units U1 to U3. In this case, discrepancies occur between an imaging area R1 by the radiation temperature sensor SE1, an imaging area R2 by the radiation temperature sensor SE2, and an imaging area R3 by the radiation temperature sensor SE3.

### [Calibration Substrate]

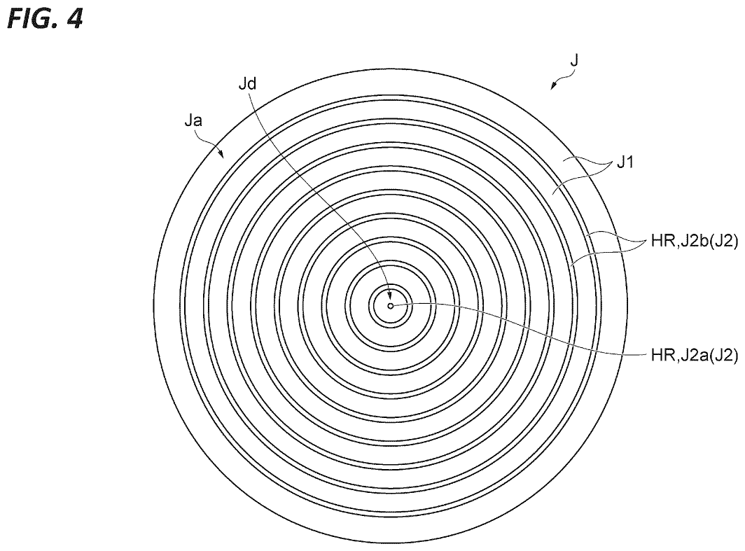

Next, the calibration substrate J will be described with reference to FIG. 4. The calibration substrate J has a circular plate-like shape and includes the upper surface Ja and the lower surface Jb, which is the opposite side of the upper surface Ja. The calibration substrate J may be substantially the same size as the substrate W. The calibration substrate J may be made of the same material as the substrate W (e.g., a semiconductor substrate (silicon wafer)).

The upper surface Ja includes a plurality of high emissivity members HR (first material). In other words, the upper surface Ja includes a portion J1 (second portion) where a material constituting the calibration substrate J is exposed, and a portion J2 (first portion) where the high emissivity members HR are exposed. The portion J2 includes a central portion J2a where the high emissivity member HR is arranged at the center Jd of the upper surface Ja, and a plurality of annular portions J2b arranged around the central portion J2a to surround the central portion J2a. In other words, the portion J2 has a substantially point-symmetrical shape centered on the central portion J2a. The central portion J2a has a circular dot-like shape. The diameter of the central portion J2a may be, for example, approximately a few millimeters. The annular portions J2b are arranged concentrically so as to be spaced apart from each other at a predetermined interval (e.g., approximately 15 mm) in the radial direction of the calibration substrate J. The width of each annular portion J2b may be, for example, approximately a few millimeters.

The emissivity (infrared emissivity) of the high emissivity member HR is higher than the emissivity (infrared emissivity) of the calibration substrate J (second material). The emissivity of the high emissivity member HR may be in the range of approximately 0.9 to 1.0. The high emissivity member HR may be, for example, an adhesive tape made of a high emissivity material (so-called “blackbody tape”). When the high emissivity member HR is an adhesive tape, the point-symmetric arrangement of the portion J2 on the upper surface Ja as described above helps prevent the center of gravity of the calibration substrate J from shifting due to the weight of the adhesive tape. The emissivity of the calibration substrate J may be less than 0.9. If the calibration substrate J is made of silicon, the emissivity of the calibration substrate J is in the range of approximately 0.3 to 0.5.

### [Controller]

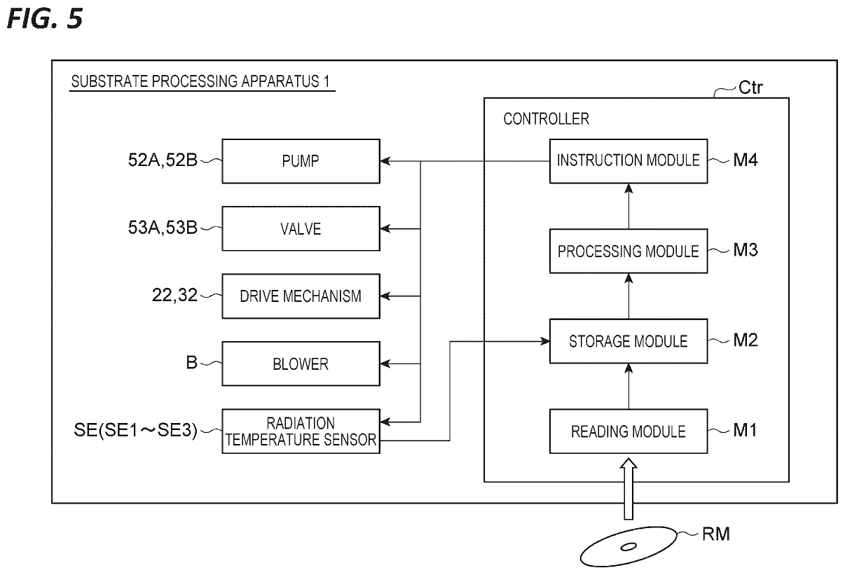

As illustrated in FIG. 5, the controller Ctr includes, as functional modules, a reading module M1, a storage module M2, a processing module M3, and an instruction module M4. These functional modules are merely conceptual divisions of the functions of the controller Ctr for convenience, and do not necessarily indicate that hardware components of the controller Ctr are physically divided into these modules. Each functional module is not limited to those realized by program execution but may also be implemented using dedicated electric circuits (e.g., logic circuits) or integrated circuits (Application Specific Integrated Circuit (APC)).

The reading module M1 is configured to read a program from a computer-readable recording medium RM. The recording medium RM records a program for operating each component of the substrate processing system 1. The recording medium RM may be, for example, a semiconductor memory, an optical recording disk, a magnetic recording disk, or a magneto-optical recording disk.

The storage module M2 is configured to store various types of data. The storage module M2 may store, for example, a program read from the recording medium RM by the reading module M1, as well as setting data input by an operator via an external input device (not illustrated). The storage module M2 may also store, for example, temperature distribution data measured by the radiation temperature sensor SE.

The processing module M3 is configured to store various types of data. The processing module M3 may be configured to generate operation signals for operating each component of the substrate processing system 1 (e.g., drive mechanisms 22 and 32, pumps 52A and 52B, valves 53A and 53B, blower B, and radiation temperature sensor SE) based on various types of data stored in the storage module M2.

The instruction module M4 is configured to transmit the operation signals generated in the processing module M3 to each component of the substrate processing system 1.

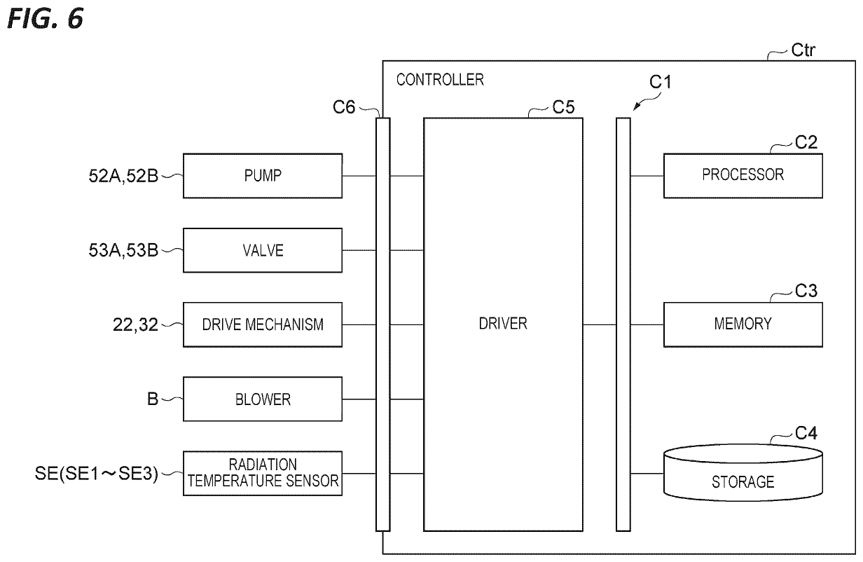

The hardware of the controller Ctr may be configured, for example, with a single control computer or multiple control computers. The controller Ctr may include, for example, circuitry C1 illustrated in FIG. 6 as a hardware configuration. The circuitry C1 may be composed of electrical circuit elements. The circuitry C1 may include, for example, a processor C2, a memory C3 (storage module), a storage C4 (storage module), a driver C5, and an input/output port C6. The processor C2 executes a program in cooperation with at least one of the memory C3 and the storage C4, and executes the input and output of signals through the input/output port C6, thereby constituting each of the above-described functional modules. The memory C3 and the storage C4 function as the storage module M2. The driver C5 is a circuit that drives each component of the substrate processing system 1. The input/output port C6 performs the input and output of signals between the driver C5 and each component of the substrate processing system 1.

The substrate processing system 1 may include a single controller Ctr, or may include a controller group (control unit) composed of multiple controllers Ctr. In the latter case, each of the aforementioned functional modules may be implemented by a single controller Ctr, or may be implemented by a combination of two or more controllers Ctr. If the controller Ctr is composed of multiple computers (circuitry C1), each of the aforementioned functional modules may be implemented by a single computer (circuitry C1), or may be implemented by a combination of two or more computers (circuitry C1). The controller Ctr may include multiple processors C2. In this case, each of the aforementioned functional modules may be implemented by a single processor C2, or may be implemented by a combination of two or more processors C2.

### [Calibration Method]

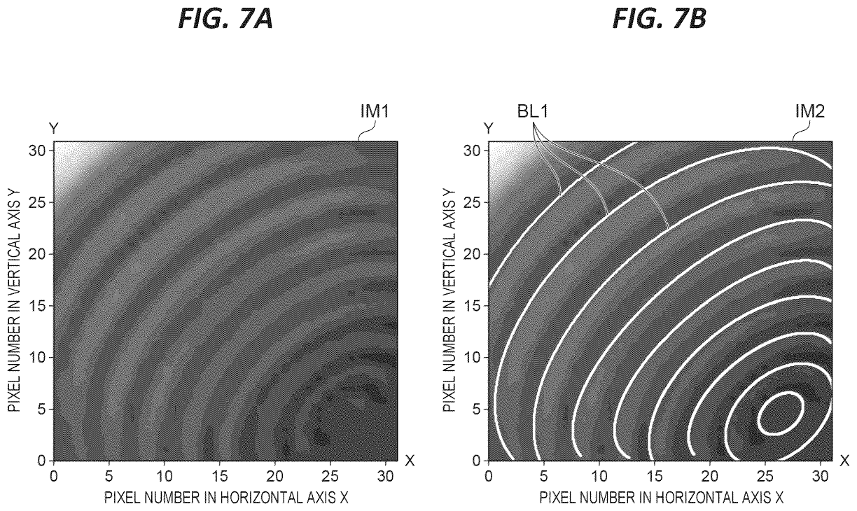

Next, a method of calibrating the radiation temperature sensor SE using the calibration substrate J will be described with reference to FIGS. 7A to 10. In the following, as an example, a method of calibrating the radiation temperature sensors SE2 and SE3 using the radiation temperature sensor SE1 as a reference, among the radiation temperature sensors SE1 to SE3 of the liquid processing units U1 to U3, will be described.

First, in the liquid processing unit U1, the controller Ctr controls the rotation unit 20, the lift unit 30, and the supply unit 50. As such, while the calibration substrate J in the supported state is rotated around the central axis Ax by the rotation unit 20, the heated processing liquid L2 is supplied to the lower surface Jb of the calibration substrate J to heat the calibration substrate J uniformly. In this state, the controller Ctr controls the radiation temperature sensor SE1 to measure the temperature distribution (first temperature distribution) of the upper surface Ja of the calibration substrate J. Since the upper surface Ja of the calibration substrate J includes the portions J1 and J2, and the radiation temperature sensor SE1 captures an image of the calibration substrate J from an obliquely upward direction, the radiation temperature sensor SE1 obtains a captured image IM1 (see, e.g., FIG. 7A) showing a temperature distribution in which bright and dark ellipses are arranged alternately. In the captured image IM1, bright areas may indicate relatively low temperatures, while dark areas may indicate relatively high temperatures. The radiation temperature sensor SE1 transmits data of the captured image IM1 (temperature distribution data) to the controller Ctr (storage module M2).

If the radiation temperature sensor SE1 is an infrared camera with 1024 pixels, a captured image IM1 is also composed of 1024 pixels. In this case, the boundary between bright and dark areas in the temperature distribution of the captured image IM1 does not form a smooth line because of the low resolution, which may affect the accuracy of boundary line extraction processing to be described later. Therefore, the controller Ctr may perform interpolation processing (e.g., linear interpolation) on the captured image IM1 acquired from the radiation temperature sensor SE1.

Next, the controller Ctr executes processing of extracting a boundary line extending along the boundary between the bright and dark areas in the temperature distribution shown in the captured image IM1. The boundary line extraction processing may include, for example, generating a binary image by binarizing the captured image IM1 using a predetermined threshold and determining contours in the binary image. The boundary line extraction processing may also include performing pre-processing such as noise removal or enhancement, before generating the binary image. FIG. 7B illustrates an example of a processed image IM2 in which a boundary line BL1 is extracted from the captured image IM1 and is then superimposed on the captured image IM1. In addition, an ellipse that substantially matches the extracted boundary line BL1 may be calculated, and the calculated ellipse may be set as a new boundary line BL1. The ellipse may be calculated, for example, based on the center, major axis, minor axis, and inclination of the extracted boundary line BL1.

The same procedure as above is also executed in the liquid processing units U2 and U3. In other words, the calibration substrate J is transferred from the liquid processing unit U1 to the liquid processing unit U2 by the transfer arm A2. Next, in the liquid processing unit U2, the radiation temperature sensor SE2 measures the temperature distribution (second temperature distribution) of the upper surface Ja of the calibration substrate J, and obtains a captured image representing the temperature distribution. Next, the controller Ctr extracts a boundary line from the captured image. Next, the calibration substrate J is transferred from the liquid processing unit U2 to the liquid processing unit U3 by the transfer arm A2. Next, in the liquid processing unit U3, the radiation temperature sensor SE3 measures the temperature distribution of the upper surface Ja of the calibration substrate J, and obtains a captured image representing the temperature distribution. Next, the controller Ctr extracts a boundary line from the captured image.

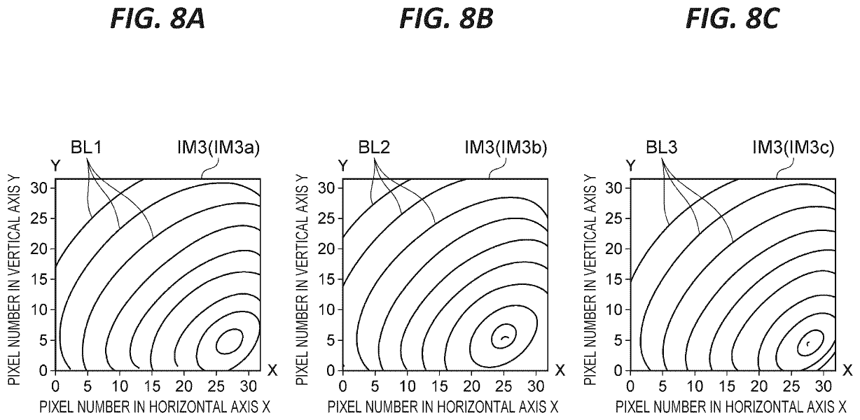

Through the above procedure, boundary lines are obtained from the captured image in each of the liquid processing units U1 to U3. The controller Ctr may generate a boundary line image IM3 that displays only the obtained boundary lines. FIG. 8A illustrates an example of a boundary line image IM3a obtained in the liquid processing unit U1. FIG. 8B illustrates an example of a boundary line image IM3b obtained in the liquid processing unit U2. FIG. 8C illustrates an example of a boundary line image IM3c obtained in the liquid processing unit U3. In addition, when generating the boundary line image IM3a, the radiation temperature sensor SE1 in the liquid processing unit U1 may acquire a plurality of captured images IM1, and the boundary lines BL1 obtained from the respective captured images IM1 may be averaged to obtain a single averaged boundary line BL1. The same applies to boundary line images IM3b and IM3c.

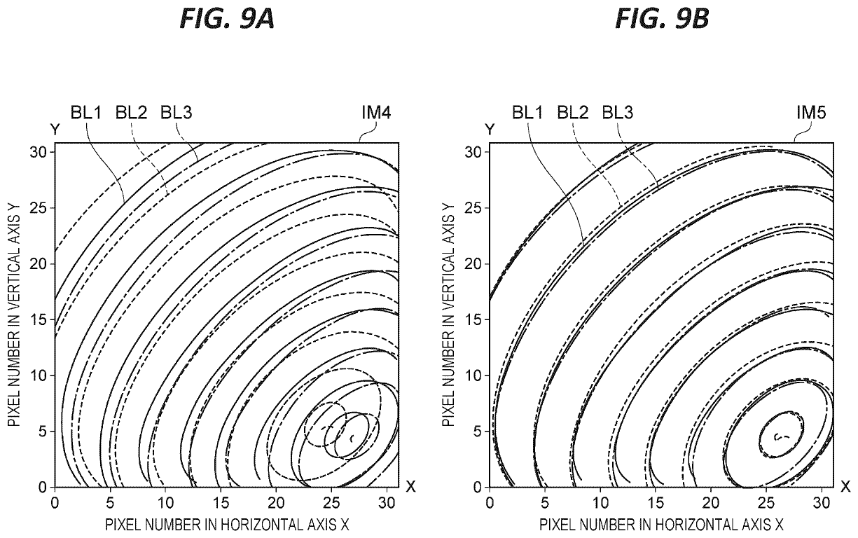

When the boundary line images IM3a to IM3c obtained in this way are simply superimposed to generate a pre-calibration image IM4, it can be seen that the boundary lines BL1 to BL3 may be misaligned, as illustrated in FIG. 9A. This misalignment of the boundary lines BL1 to BL3 occurs due to discrepancies in the attachment positions or attachment angles of the radiation temperature sensors SE1 to SE3 relative to the housing 10.

It is assumed that the horizontal pixel row number is denoted by X (where X is an integer between 0 and 31) and the vertical pixel column number is denoted by Y (where Y is an integer between 0 and 31), such that each of 1024 pixels is represented as (X, Y). A case where the radial position of the substrate W corresponding to each pixel number is set identically across the radiation temperature sensors SE1 to SE3 is considered. An example of the correspondence between the pixel number and the radial position of the substrate W is illustrated below.

| X | Y | Radial Position (mm) |
|---|---|---|
| 27 | 4 | 10 |
| 26 | 5 | 20 |
| 24 | 7 | 35 |
| 22 | 9 | 50 |
| 20 | 11 | 60 |
| 17 | 14 | 80 |
| 14 | 17 | 97 |
| 11 | 20 | 113 |
| 8 | 23 | 125 |
| 5 | 26 | 140 |

However, as described above, when the boundary lines BL1 to BL3 are misaligned, at least two of the radiation temperature sensors SE1 to SE3 will have discrepancies between the actual radial position of the substrate W and the preset radial position corresponding to the pixel number. In other words, when the correspondence between the pixel number and the radial position of the substrate W is identical across all of the radiation temperature sensors SE1 to SE3, the preset radial position of the substrate W corresponding to a predetermined pixel number will differ from the actually measured radial position of the substrate W corresponding to the predetermined pixel number. In this case, even when the actual substrates W processed in the liquid processing units U1 to U3 all have the same temperature distribution, the measured temperature distribution results by the radiation temperature sensors SE1 to SE3 may deviate from the actual values.

Therefore, as illustrated in FIG. 9B, the controller Ctr calibrates the measurement target positions of the radiation temperature sensors SE1 to SE3 such that the boundary lines BL2 and BL3 are substantially superimposed on the boundary line BL1 of the boundary line image Im3a, which serves as a reference. When the boundaries BL2 and BL3 are substantially superimposed on the boundary line BL1, the boundary line images IM3b and IM3c may be moved (e.g., translated or rotated) relative to the boundary line image IM3a to maximize the similarity between two images being compared. The alignment between the boundary line image IM3a and the boundary line images IM3b and IM3c may be a so-called “rigid alignment.” The determination of whether the boundary lines BL2 and BL3 are substantially superimposed on the boundary line BL1 may be based on an evaluation function indicating the similarity between two images being compared. The evaluation function may include, for example, the sum of squared differences (SSD), the sum of absolute differences (SAD), normalized cross-correlation (NCC), or mutual information.

Here, calibrating the measurement target position based on the boundary line BL1 involves executing the following calculation processing and update processing. The calculation processing includes calculating new radial positions to be set for each corresponding pixel number in the radiation temperature sensors SE2 and SE3 based on the movement amount of the boundary line images IM3b and IM3c relative to the boundary line image IM3a and the preset radial position corresponding to each pixel number in the radiation temperature sensor SE1. For example, affine transformation or similar techniques may be used to calculate the radial position. The update processing includes newly setting (updating), for each pixel number, the radial position calculated for each pixel number in the calculation processing. Specifically, when a previous radial position r1 (X_old, Y_old) is set for a single arbitrary pixel number, and a new radial position r2 (X_new, Y_new) for the single pixel number is calculated in the calculation processing, the update processing replaces (rewrites) r1 (X_old, Y_old) with r2 (X_new, Y_new). This ensures that the temperature acquired at a pixel corresponding to the single pixel number in the radiation temperature sensor SE1 is associated with the radial position r2 of the substrate W, rather than with the radial position r1.

### [Actions]

According to the above examples, the radiation temperature sensor SE is calibrated using the calibration substrate J, which includes the upper surface Ja composed of the portion J2 where the high emissivity member HR is exposed and the portion J1 where the material constituting the calibration substrate J having a lower emissivity than the high emissivity member HR is exposed. In other words, in a state where the calibration substrate J is heated by the heated processing liquid L2 supplied to the lower surface Jb side of the calibration substrate J, the radiation temperature sensor SE measures the temperature distribution of the upper surface Ja, making the boundary between the portion J1 and the portion J2 distinct. Therefore, the boundary line at the same position on the upper surface Ja is obtained as a reference position by measuring the temperature distribution of the upper surface Ja of the calibration substrate J in each liquid processing unit U. As a result, the measurement target position (radial position at each pixel number) may be redefined in the radiation temperature sensor SE of each liquid processing unit U such that the boundary lines are substantially superimposed. This allows for the calibration of the radiation temperature sensor SE1 without changing the position of the radiation temperature sensor SE arranged in the liquid processing unit U for processing the substrate W.

According to the above examples, the portion J2 may include the dot-shaped central portion J2a where the high-emissivity member HR is arranged at the center of the calibration substrate J, and the annular portion J2b where the high-emissivity members HR are arranged around the central portion J2a to surround the central portion J2a. In this case, when measuring the temperature distribution of the upper surface Ja using the radiation temperature sensor SE, a dot-shaped boundary located at the center of the upper surface Ja and an annular boundary surrounding the dot-shaped boundary are obtained as boundary lines. Therefore, it is possible to calibrate the radiation temperature sensor SE1 with higher accuracy by redefining the measurement target position (radial position at each pixel number) in the radiation temperature sensor SE of each liquid processing unit U such that the boundary lines are substantially superimposed.

According to the above examples, the calibration substrate J may be transferred between the liquid processing unit U and the shelf unit 6 by the transfer arm A2. In this case, it is possible to retract the calibration substrate J to the shelf unit 6 during substrate processing by the liquid processing unit U.

According to the above examples, the calibration substrate J may be heated by supplying the heated processing liquid L2 (heating fluid) to the lower surface Jb from below the lower surface Jb during the rotation of the calibration substrate J by the rotation unit 20. In this case, it is possible to heat the entire calibration substrate J uniformly in a simplified manner.

According to the above examples, the calibration substrate J may be heated by supplying hot water to the lower surface Jb from below the lower surface Jb during the rotation of the calibration substrate J by the rotation unit 20. In this case, since hot water is used as a heating fluid for the calibration substrate J, it is possible to heat the entire calibration substrate J uniformly in a simplified low-cost manner.

### Modification

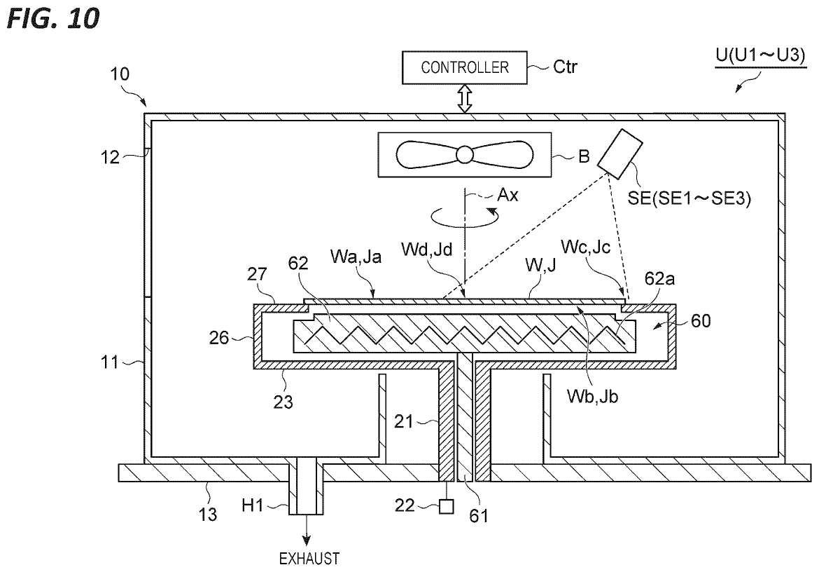

(1) As illustrated in FIG. 10, the liquid processing unit U may have a different configuration for the rotation unit 20 from the liquid processing unit U illustrated in FIG. 2, and may also include a heating module 60 instead of the cover member 40 and the supply unit 50. The rotation unit 20 includes a sidewall 26 extending upward from the peripheral edge of the support plate 23, and a support wall 27 extending radially inward from the upper end of the sidewall 26. The support wall 27 is configured to support the substrate W or the calibration substrate J on the upper surface of the inner periphery.

The heating module 60 includes a support shaft 61 and a hot plate 62 connected to the upper end of the support shaft 61. The hot plate 62 is located below the substrate W or the calibration substrate J supported by the support wall 27. The hot plate 62 is configured to operate based on an operation signal from the controller Ctr and to heat the substrate W or the calibration substrate J supported by the support wall 27. The hot plate 62 may incorporate a heat source 62a (e.g., a heater). According to the example of FIG. 10, it is possible to heat the entire calibration substrate J uniformly in a simplified manner.

In addition, the hot plate 62 may be configured to heat the substrate W or the calibration substrate J while being in contact with or in non-contact with the lower surface Wb of the substrate W or the lower surface Jb of the calibration substrate J supported by the support wall 27. Further, in the example of FIG. 10, the substrate W or the calibration substrate J may be rotating or remain stationary during the heating of the substrate W or the calibration substrate J, or during the measurement of the temperature distribution of the substrate W or the calibration substrate J by the radiation temperature sensor SE.

(2) In the above examples, the calibration substrate J is transferred to each of the liquid processing units U included in the substrate processing system 1, and the radiation temperature sensor SE is provided for each liquid processing unit U. However, the radiation temperature sensor SE and the calibration substrate J may be arranged in a calibration device separate from the substrate processing system 1, and the calibration device may perform the calibration of the radiation temperature sensor SE. In this case, the calibration device may include at least a support for supporting the calibration substrate J and a heating unit for heating the calibration substrate J, and may further include a rotation unit for rotating the calibration substrate J.

(3) The blower B does not necessarily have to be located at the upper center of the housing 10. Alternatively, the liquid processing unit U may not include the blower B. In such cases, the radiation temperature sensor SE may be arranged directly above the substrate W or the calibration substrate J.

(4) The shape of the portion J2 provided on the upper surface Ja of the calibration substrate J is not particularly limited. The number of portions J2 provided on the upper surface Ja of the calibration substrate J may be one or multiple. When there is one portion J2, the shape of the portion J2 may be polygonal, irregular, or any other form. When there are multiple portions J2, the shapes of the respective portions J2 may all be substantially the same, at least one of them may be different, or they may all be different. When there are multiple portions J2, the sizes of the respective portions J2 may all be substantially the same, at least one of them may be different, or they may all be different.

(5) The substrate W or the calibration substrate J may also be held by other holding units such as an adsorption chuck or a vacuum chuck.

(6) The technique disclosed herein may also be applied to a substrate processing system configured to process a substrate by supplying a process gas to a chamber that accommodates the substrate and generating a plasma.

### OTHER EXAMPLES

Example 1. An example of a substrate processing apparatus includes a holding unit that holds a substrate or a calibration substrate, a heating unit that heats the substrate or the calibration substrate held by the holding unit, and a radiation temperature sensor that detects infrared radiation emitted from the substrate or the calibration substrate and measure temperature distribution of the substrate or the calibration substrate. The calibration substrate includes a first main surface facing the heating unit and a second main surface opposite the first main surface and measured for temperature distribution by the radiation temperature sensor. The second main surface includes a first portion where a first material is exposed, and a second portion where a second material with a lower emissivity than the first material is exposed.

Incidentally, to measure the temperature distribution of the substrate in substrate processing, the radiation temperature sensor is provided inside each processing chamber that processes the substrate. However, When the attachment position of the radiation temperature sensor relative to the processing chamber is not consistent among processing chambers, misalignment may occur in the measurement target position of the radiation temperature sensor on the substrate. In particular, when a blower is arranged in the upper region of the processing chamber to generate a downward airflow in the inside of the processing chamber, the radiation temperature sensor needs to measure the temperature distribution of the substrate surface from an obliquely upward direction to avoid the blower. In this case, it may be difficult to attach the radiation temperature sensor at substantially the same position inside each processing chamber. Additionally, in general, since the infrared emissivity of the substrate is low and the infrared emissivity of the entire substrate surface is substantially uniform, it is difficult to set a measurement reference when measuring the temperature distribution of the substrate surface using the radiation temperature sensor.

However, according to Example 1, the radiation temperature sensor is calibrated using the calibration substrate that includes the second main surface composed of the first portion where the first material is exposed and the second portion where the second material having a lower emissivity than the first material is exposed. In other words, when the calibration substrate is heated by the heating unit from the first main surface side of the calibration substrate, and the radiation temperature sensor measures the temperature distribution of the second main surface, the boundary between the first and second portions becomes distinct. Accordingly, the boundary at the same position on the second main surface is obtained as a reference position by measuring the temperature distribution of the second main surface of the calibration substrate in each processing chamber. As a result, by redefining the measurement target position of the radiation temperature sensor in each processing chamber such that the reference positions are substantially superimposed, it is possible to calibrate the radiation temperature sensor without changing the position of the radiation temperature sensor arranged inside the processing chamber that processes the substrate.

Example 2. The apparatus according to Example 1, wherein the radiation temperature sensor may be configured to measure temperature distribution in a region of the second main surface that includes a center and a peripheral edge of the calibration substrate.

Example 3. The apparatus according to Example 1 or 2, wherein the first portion may include a dot-shaped central portion where the first material is arranged at the center of the calibration substrate, and an annular portion where the first material is arranged around the central portion to surround the central portion. In this case, when measuring the temperature distribution of the second main surface using the radiation temperature sensor, a dot-shaped boundary located at the center of the second main surface and an annular boundary surrounding the dot-shaped boundary are obtained as reference positions. Therefore, by redefining the measurement target position of the radiation temperature sensor in each processing chamber such that the reference positions are substantially superimposed, it is possible to calibrate the radiation temperature sensor with higher accuracy.

Example 4. The apparatus according to any one of Examples 1 to 3, wherein the emissivity of the first material may be in a range of 0.9 to 1.0.

Example 5. The apparatus according to any one of Examples 1 to 4, wherein the second material may be silicon.

Example 6. The apparatus according to any one of Examples 1 to 5, further including a processing chamber that accommodates the holding unit, the heating unit, and the radiation temperature sensor and processes the substrate, an accommodation chamber that accommodates the calibration substrate, and a transfer section that transfers the calibration substrate between the processing chamber and the accommodation chamber. In this case, it is possible to retract the calibration substrate to the accommodation chamber during substrate processing in the processing chamber.

Example 7. The apparatus according to any one of Examples 1 to 6, wherein the holding unit may be configured to rotate the calibration substrate about a rotation axis extending in a vertical direction, while holding the calibration substrate substantially horizontally, with the second main surface facing upward and the first main surface facing downward, and the heating unit may be configured to heat the calibration substrate by supplying a heating fluid to the first main surface from below the first main surface during rotation of the calibration substrate by the holding unit. In this case, it is possible to heat the entire calibration substrate uniformly in a simplified manner.

Example 8. The apparatus according to Example 7, wherein the heating unit may be configured to heat the calibration substrate by supplying hot water to the first main surface from below the first main surface during rotation of the calibration substrate by the holding unit. In this case, since hot water is used as a heating fluid for the calibration substrate, it is possible to heat the entire calibration substrate uniformly in a simplified low-cost manner.

Example 9. The apparatus according to any one of Examples 1 to 6, wherein the holding unit may be configured to hold the calibration substrate substantially horizontally, with the second main surface facing upward and the first main surface facing downward, and the heating unit may be a hot plate arranged below the first main surface of the calibration substrate held by the holding unit to heat the first main surface. In this case, it is possible to heat the entire calibration substrate uniformly in a simplified manner.

Example 10. The apparatus according to any one of Examples 1 to 9, further including a first processing chamber and a second processing chamber, both configured to process the substrate, and a control unit, wherein the first processing chamber accommodates the holding unit, the heating unit, and the radiation temperature sensor, wherein the second processing chamber accommodates another holding unit configured to hold the substrate or the calibration substrate, another heating unit configured to heat the substrate or the calibration substrate held by the another holding unit, and another radiation temperature sensor configured to detect infrared radiation emitted from the substrate or the calibration substrate to measure temperature distribution of the substrate or the calibration substrate, and wherein the control unit is configured to execute a first processing of acquiring data of the first temperature distribution from the radiation temperature sensor by measuring first temperature distribution of the second main surface using the radiation temperature sensor in a state where the calibration substrate held by the holding unit is heated by the heating unit, a second processing of acquiring data of the second temperature distribution from the another radiation temperature sensor by measuring second temperature distribution of the second main surface using the another radiation temperature sensor in a state where the calibration substrate held by the another holding unit is heated by the another heating unit, and a third processing of calibrating a measurement target position of the another radiation temperature sensor such that a portion of the first temperature distribution indicating a boundary between the first and second materials and a portion of the second temperature distribution indicating a boundary between the first and second materials are substantially superimposed. In this case, the boundary of the first temperature distribution obtained by the radiation temperature sensor accommodated in the first processing chamber and the boundary of the second temperature distribution obtained by the another radiation temperature sensor accommodated in the second processing chamber are obtained as reference positions, respectively. Therefore, by redefining the measurement target position of the another radiation temperature sensor such that these reference positions are substantially superimposed, it is possible to calibrate the another radiation temperature sensor without changing the position of the another radiation temperature sensor.

Example 11. An example of a calibration substrate is a calibration substrate that calibrates a measurement target position of a radiation temperature sensor for measuring temperature distribution of a substrate. One example of the calibration substrate includes a first main surface, and a second main surface opposite the first main surface and measured for temperature distribution by the radiation temperature sensor. The second main surface includes a first portion where a first material is exposed, and a second portion where a second material with a lower emissivity than the first material is exposed. In this case, similar effects to those of the apparatus according to Example 1 are obtained.

Example 12. The calibration substrate according to Example 11, wherein the first portion may include a dot-shaped central portion where the first material is arranged at a center of the calibration substrate, and an annular portion where the first material is arranged around the central portion to surround the central portion. In this case, similar effects to those of the apparatus in Example 3 are obtained.

Example 13. The calibration substrate according to Example 11 or 12, wherein the emissivity of the first material may be in a range of 0.9 to 1.0.

Example 14. The calibration substrate according to any one of Examples 11 to 13, wherein the second material may be silicon.

Example 15. One example of a calibration method is a method of calibrating a measurement target position, between a first radiation temperature sensor arranged inside a first processing chamber and a second radiation temperature sensor arranged in a second processing chamber, using a calibration substrate. The calibration substrate includes a first main surface, and a second main surface opposite the first main surface. The second main surface includes a first portion where a first material is exposed, and a second portion where a second material with a lower emissivity than the first material is exposed. The calibration method includes a first step of acquiring first temperature distribution of the second main surface from the first radiation temperature sensor by detecting infrared radiation from the second main surface using the first radiation temperature sensor in a state where the first main surface of the calibration substrate held by a first holding unit arranged inside the first processing chamber is heated by a first heating unit arranged inside the first processing chamber, a second step of acquiring second temperature distribution of the second main surface from the second radiation temperature sensor by detecting infrared radiation from the second main surface using the second radiation temperature sensor in a state where the first main surface of the calibration substrate held by a second holding unit arranged inside the second processing chamber is heated by a second heating unit arranged inside the second processing chamber, and a third step of calibrating a measurement target position of the second radiation temperature sensor such that a portion of the first temperature distribution indicating a boundary between the first and second materials and a portion of the second temperature distribution indicating a boundary between the first and second materials are substantially superimposed. In this case, similar effects to those in Examples 1 and 10 are obtained.

Example 16. The method according to Example 15, wherein the first step may include measuring temperature distribution of a region of the second main surface that includes a center and a peripheral edge of the calibration substrate using the first radiation temperature sensor, and wherein the second step may include measuring temperature distribution of a region of the second main surface that includes the center and the peripheral edge of the calibration substrate using the second radiation temperature sensor.

Example 17. The method according to Example 15 or 16, wherein the first portion may include a dot-shaped central portion where the first material is arranged at the center of the calibration substrate, and an annular portion where the first material is arranged around the central portion to surround the central portion. In this case, similar effects to those of the apparatus in Example 3 are obtained.

Example 18. The method according to any one of Examples 15 to 17, wherein the emissivity of the first material may be in a range of 0.9 to 1.0.

Example 19. The method according to any one of Examples 15 to 18, wherein the second material may be silicon.

Example 20. The method according to any one of Examples 15 to 18, wherein the first step may include heating the calibration substrate by supplying a heating fluid to the first main surface from below the first main surface using the first heating unit, in a state where the calibration substrate is rotated about a rotation axis extending in a vertical direction, while holding the calibration substrate substantially horizontally using the first holding unit, with the second main surface facing upward and the first main surface facing downward, and wherein the second step may include heating the calibration substrate by supplying the heating fluid to the first main surface from below the first main surface using the second heating unit, in a state where the calibration substrate is rotated about the rotation axis extending in the vertical direction, while holding the calibration substrate substantially horizontally using the second holding unit, with the second main surface facing upward and the first main surface facing downward. In this case, similar effects to those of the apparatus in Example 7 are obtained.

A substrate processing apparatus, a calibration substrate, and a calibration method according to the present disclosure enable the calibration of a radiation temperature sensor, arranged inside a processing chamber for processing a substrate, without changing the position of the radiation temperature sensor.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a holder configured to hold a substrate or a calibration substrate;
a heater configured to heat the substrate or the calibration substrate held by the holder; and
a radiation temperature sensor configured to detect infrared radiation emitted from the substrate or the calibration substrate and measure temperature distribution of the substrate or the calibration substrate,
wherein the calibration substrate includes:
a first main surface facing the heater and
a second main surface opposite the first main surface and measured for temperature distribution by the radiation temperature sensor,
the second main surface includes:
a first portion where a first material is exposed, and
a second portion where a second material with a lower emissivity than the first material is exposed.

2. The substrate processing apparatus according to claim 1, wherein the radiation temperature sensor is configured to measure temperature distribution in a region of the second main surface that includes a center and a peripheral edge of the calibration substrate.

3. The substrate processing apparatus according to claim 1, wherein the first portion includes:
a dot-shaped central portion where the first material is arranged at the center of the calibration substrate, and
an annular portion where the first material is arranged around the central portion to surround the central portion.

4. The substrate processing apparatus according to claim 1, wherein the emissivity of the first material is in a range of 0.9 to 1.0.

5. The substrate processing apparatus according to claim 1, wherein the second material is silicon.

6. The substrate processing apparatus according to claim 1, further comprising:
a processing chamber accommodating the holder, the heater, and the radiation temperature sensor, and configured to process the substrate;
an accommodation chamber configured to accommodate the calibration substrate; and
a transfer section configured to transfer the calibration substrate between the processing chamber and the accommodation chamber.

7. The substrate processing apparatus according to claim 1, wherein the holder is configured to rotate the calibration substrate about a rotation axis extending in a vertical direction, while holding the calibration substrate substantially horizontally, with the second main surface facing upward and the first main surface facing downward, and
the heater is configured to heat the calibration substrate by supplying a heating fluid to the first main surface from below the first main surface during rotation of the calibration substrate by the holder.

8. The substrate processing apparatus according to claim 7, wherein the heater is configured to heat the calibration substrate by supplying hot water to the first main surface from below the first main surface during rotation of the calibration substrate by the holder.

9. The substrate processing apparatus according to claim 1, wherein the holder is configured to hold the calibration substrate substantially horizontally, with the second main surface facing upward and the first main surface facing downward, and
the heater is a hot plate arranged below the first main surface of the calibration substrate held by the holder to heat the first main surface.

10. The substrate processing apparatus according to claim 1, further comprising:
a first processing chamber and a second processing chamber, both configured to process the substrate, and
a controller,
wherein the first processing chamber accommodates the holder, the heater, and the radiation temperature sensor,
the second processing chamber accommodates:
another holder configured to hold the substrate or the calibration substrate,
another heater configured to heat the substrate or the calibration substrate held by the another holder, and
another radiation temperature sensor configured to detect infrared radiation emitted from the substrate or the calibration substrate to measure temperature distribution of the substrate or the calibration substrate,
the controller is configured to:
acquire data of first temperature distribution from the radiation temperature sensor after measuring the first temperature distribution of the second main surface using the radiation temperature sensor in a state where the calibration substrate held by the holder is heated by the heater,
acquire data of second temperature distribution from the another radiation temperature sensor after measuring the second temperature distribution of the second main surface using the another radiation temperature sensor in a state where the calibration substrate held by the another holder is heated by the another heater, and
calibrate a measurement target position of the another radiation temperature sensor such that a portion of the first temperature distribution indicating a boundary between the first and second materials and a portion of the second temperature distribution indicating a boundary between the first and second materials are substantially superimposed.

11. A calibration substrate that calibrates a measurement target position of a radiation temperature sensor for measuring temperature distribution of a substrate, the calibration substrate comprising:
a first main surface; and
a second main surface opposite the first main surface and measured for temperature distribution by the radiation temperature sensor,
wherein the second main surface includes:
a first portion where a first material is exposed, and
a second portion where a second material with a lower emissivity than the first material is exposed.

12. The calibration substrate according to claim 11, wherein the first portion includes:
a dot-shaped central portion where the first material is arranged at a center of the calibration substrate, and
an annular portion where the first material is arranged around the central portion to surround the central portion.

13. The calibration substrate according to claim 11, wherein the emissivity of the first material is in a range of 0.9 to 1.0.

14. The calibration substrate according to claim 11, wherein the second material is silicon.

15. A method of calibrating a measurement target position between a first radiation temperature sensor arranged inside a first processing chamber and a second radiation temperature sensor arranged in a second processing chamber using a calibration substrate, the calibration substrate including:
a first main surface, and
a second main surface opposite the first main surface, wherein the second main surface includes:
a first portion where a first material is exposed, and
a second portion where a second material with a lower emissivity than the first material is exposed,
the method comprising:
acquiring first temperature distribution of the second main surface from the first radiation temperature sensor by detecting infrared radiation from the second main surface using the first radiation temperature sensor in a state where the first main surface of the calibration substrate held by a first holder arranged inside the first processing chamber is heated by a first heater arranged inside the first processing chamber,
acquiring second temperature distribution of the second main surface from the second radiation temperature sensor by detecting infrared radiation from the second main surface using the second radiation temperature sensor in a state where the first main surface of the calibration substrate held by a second holder arranged inside the second processing chamber is heated by a second heater arranged inside the second processing chamber, and
calibrating a measurement target position of the second radiation temperature sensor such that a portion of the first temperature distribution indicating a boundary between the first and second materials and a portion of the second temperature distribution indicating a boundary between the first and second materials are substantially superimposed.

16. The method according to claim 15, wherein the acquiring the first temperature distribution includes measuring temperature distribution of a region of the second main surface that includes a center and a peripheral edge of the calibration substrate using the first radiation temperature sensor, and
the acquiring the second temperature distribution includes measuring temperature distribution of a region of the second main surface that includes the center and the peripheral edge of the calibration substrate using the second radiation temperature sensor.

17. The method according to claim 15, wherein the first portion includes:
a dot-shaped central portion where the first material is arranged at the center of the calibration substrate, and
an annular portion where the first material is arranged around the central portion to surround the central portion.

18. The method according to claim 15, wherein the emissivity of the first material is in a range of 0.9 to 1.0.

19. The method according to claim 15, wherein the second material is silicon.

20. The method according to claim 15, wherein the acquiring the first temperature distribution includes heating the calibration substrate by supplying a heating fluid to the first main surface from below the first main surface using the first heater in a state where the calibration substrate is rotated about a rotation axis extending in a vertical direction while holding the calibration substrate substantially horizontally using the first holder, with the second main surface facing upward and the first main surface facing downward, and
the acquiring the second temperature distribution includes heating the calibration substrate by supplying the heating fluid to the first main surface from below the first main surface using the second heater in a state where the calibration substrate is rotated about the rotation axis extending in the vertical direction while holding the calibration substrate substantially horizontally using the second holder, with the second main surface facing upward and the first main surface facing downward.
